(19) United States
(12) Patent Application Publication
(10) Pub. No.: US 2013/0084685 A1
(43) Pub. Date: Apr. 4, 2013

(54) Methods for Ion Implantation

(71) Applicant: Buh-Kuan Fang, Zhubei City (TW)

(72) Inventor: Buh-Kuan Fang, Zhubei City (TW)

(73) Assignee: Taiwan Semiconductor Manufacturing Company, Ltd., Hsin-Chu (TW)

(21) Appl. No.: 13/250,483

(22) Filed: Sep. 30, 2011

(51) Int. Cl. H01L 21/336; H01L 21/425

(52) U.S. Cl. 438/301; 438/514; 257/E21.473; 257/E21.409

(57) ABSTRACT

Methods for ion implantation. A method comprises forming a layer of non-crosslinking mask material over a semiconductor region; forming a patterned photoresist layer over the non-crosslinking mask layer; removing the photoresist layer and the non-crosslinking mask layer from the exposed regions, while the masked regions remain covered; and implanting dopant ions into the exposed regions, the dopant ions being blocked from the masked regions. The non-crosslinking mask layer and any remaining photoresist material may be removed. In additional embodiments, the non-crosslinking material comprises carbon. In another embodiment, the non-crosslinking material comprises an oxide. Ion implantations for source and drain, lightly doped drain, and well regions are performed.

### BACKGROUND

A common requirement for an advanced electronic circuit and particularly advanced technology semiconductor processes is the need to accurately perform ion implantation in selected regions. The ion implantations can be used to create doped semiconductor areas such as source and drain regions in semiconductor transistor devices, for example.

Masking is used in semiconductor processing to define masked areas where the ions are prevented from entering the material. In other regions, the mask material is removed prior to the implantation step to expose portions of the semiconductor material and allow the implant ions to enter the material. Photolithography may be used to define the masked and exposed regions. Ion implantation is then performed over the exposed and masked semiconductor regions.

As semiconductor processes continue to advance, the ion implantation dosages have been increasing with increased concentrations in the doped regions. The photoresist mask material is increasingly hard to remove after ion implantation. The process chemistries used to remove the hardened photoresist include fluorine based chemistry that may damage structures and materials within the substrate, such as Si, SiO2, and high and low k dielectric materials. Fluorine based chemicals may be effective to remove residues but the application of these materials may be time limited in order to prevent unwanted damage.

A continuing need thus exists for ion implantation mask methods that overcome the disadvantages of the prior art approaches.

### BRIEF DESCRIPTION OF THE FIGURES

For a more complete understanding of the embodiments, and the advantages thereof, reference is now made to the following descriptions taken in conjunction with the accompanying drawings, in which:

FIG. 1 illustrates in a cross sectional view an intermediate structure for use with the embodiments;

FIG. 2 depicts in a cross sectional view the structure of FIG. 1 following additional processing;

FIG. 3 depicts in a cross sectional view the structure of FIG. 2 following additional processing;

FIG. 4 depicts in a cross sectional view the structure of FIG. 3 following additional processing; and

FIG. 5 depicts in a flow diagram, an example method embodiment.

The drawings, schematics and diagrams are illustrative and not intended to be limiting, but are examples of embodiments of the invention, are simplified for explanatory purposes, and are not drawn to scale.

### DETAILED DESCRIPTION

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Example embodiments which are now described in detail provide ion implantation mask methods for semiconductor processing. In embodiments, a layer of non-cros slinking strippable hard mask material (“SHL”) is formed over a semiconductor layer to be implanted with ions, or doped. A photoresist layer is formed over the SHL. A photolithographic process is used to pattern the photoresist layers. A photoresist exposure and develop step is used to pattern the photoresist and remove the photoresist that is over the areas to be exposed to the ions—the unmasked regions. In a removal step, the photoresist lying over the masked areas, and the strippable hard mask layer over the unmasked regions, are removed to define exposed and masked areas. This removal may be done by ashing, etching or a combination of these. Ion implantation is performed over the semiconductor region and the remaining strippable hard mask layer in the masked regions. Following the ion implantation, the remaining PR and SHL material is easily stripped from the masked regions using ashing, or etching. The ions impacting on the SHL during the ion implantation do not form hardened or crusty areas; and so the SHL material is easily completely removed using conventional PR stripping methods without the need for harsh chemicals and extended process times that might otherwise be needed.

In an example embodiment, a layer of carbon containing strippable hard mask material is first deposited over a semiconductor region to be implanted. Photoresist is then applied over the carbon containing SHL material. The photoresist is patterned by photolithography including an exposure using a photomask to define masked and unmasked regions, and development of the photoresist to expose the unmasked regions for implantation while the masked regions remain covered. During the removal of the photoresist over the unmarked regions that are to be implanted, the SHL material over the unmasked regions is also removed. The masked regions remain covered by the SHL and may have some of the photoresist remaining. Ion implantations are performed over the substrate. The unmasked regions receive the ions into the semiconductor or other material to be doped with ions. The masked regions receive the ions, which are blocked by the SHL.

The remaining photoresist and SHL are then easily removed. Because the SHL is a non-crosslinking material, it does not form polymer chains or cross-linked portions and become crusty or hard during ion implantation. It is then easily removed after ion implantation and when it is removed, the overlying PR layer is also easily removed.

The SHL materials may include other easily removed, non-crosslinking layers that do not become hard or crusty during ion implantation. Oxides such as SiO2 are one non-limiting example of such materials and provide additional alternative embodiments. The SHL layers may be combined with other liners, anti-reflective coatings, and films such as BARC layers.

The methods may be applied to any ion implantation step which uses PR as a mask. The advantages of the methods are particularly significant when the ion implant energy levels and dopant concentrations increase, such as in present and future advanced high performance semiconductor processes. The method embodiments are applicable to a variety of implantation applications, such as, without limitation, embodiments forming lightly doped drain (LDD) regions, source and drain regions, and well formation. The use of the embodiments increases yield and improves uniform process control for these advanced semiconductor processes by allowing easy removal of the mask layers following an implant step. Chemical etches or dry etches which may damage the underlying materials are not required after an implant step. This is in sharp contrast to the conventional approaches, and use of the embodiments reduces damage and increases device yield over the conventional approaches.

In particular, the methods are advantageous when ion implants to form dopant concentrations greater than 1×10¹⁴/cm² are performed. In embodiments the dopant concentration can range from 1×10^{14/cm}² to 5×10¹⁶/cm², as examples.

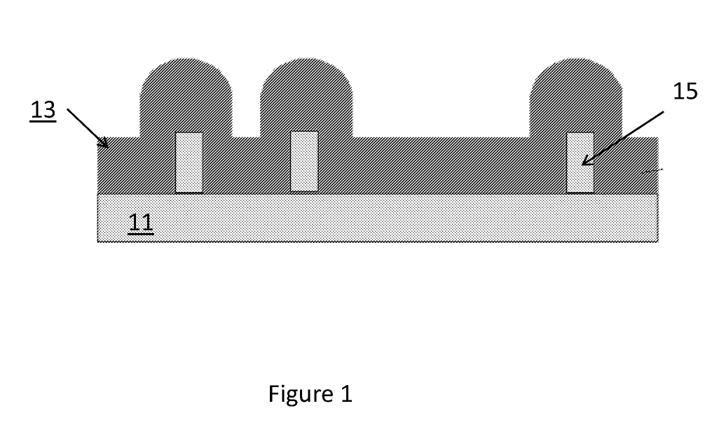

FIG. 1 depicts in a cross section a semiconductor region 11 at an intermediate process step for illustrating an embodiment. Semiconductor region 11 may, in one embodiment, be a semiconductor substrate such as may be used to form planar transistors, for example. In a non-limiting example semiconductor region 11 may be a silicon wafer or portion thereof. In other embodiments, semiconductor region 11 may be, for another non-limiting example, an epitaxially grown semiconductor material over an insulator (not shown) or “SOI” layer. In yet other embodiments, semiconductor region 11 may be, for example, a semiconductor “fin” as are used in finFET devices. The pillars or rectangular shapes 15 in FIG. 1 may be, for example, gate electrodes such as, without limitation, polysilicon gate electrodes. In a self-aligned process for forming planar FET transistors, the gate electrodes may be used as masks for ion implantations of the lightly doped drain (“LDD”) regions or to form self-aligned source and drain regions through ion implants. Typically the gate electrode will also have dielectric sidewalls (not shown) formed to space the source and drain implants from the gate region.

A layer of a strippable hard mask 13 is shown overlying the semiconductor region 11 and the gate electrodes 15. The strippable hard mask 13 is formed of materials that are non-crosslinking under ion implantation. Cross-linking is the formation of polymer chains. Cross-linking occurs in photoresist materials during ion implantation. In one embodiment, the strippable hard mask layer 13 is formed of a carbon containing layer, and in another embodiment, is formed of an amorphous carbon containing layer. In still other embodiments, a silicon dioxide layer such as SiO2 may be used for layer 13. The strippable hard mask material 13 may, in alternative embodiments, be any non-crosslinking material that is strippable by dry or wet etch chemistry processes that remove photoresist. Plasma ashing with O₂, N₂ and H₂ species are example removal processes, as are chemical wet strippers.

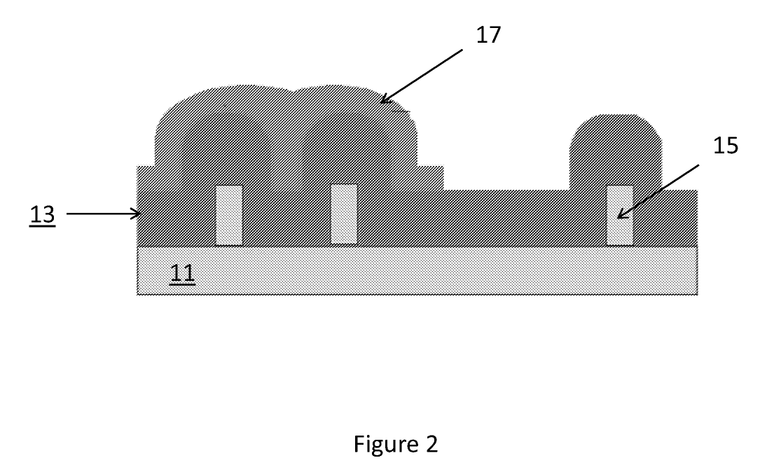

FIG. 2 depicts in a cross section the structure of FIG. 1 following additional process steps. In FIG. 2, a photoresist 17 has been deposited over the whole semiconductor region and over the strippable mask layer 13, and patterned using photolithography. Radiation such as extreme UV, UV, light, e-beam and other photolithographic processes may be used. The patterned photoresist was then developed and the portion overlying the unmasked region has been removed. The cross sectional view of FIG. 2 depicts the photoresist 17 overlying the strippable hard mask layer 13 in a masked region after the photoresist development.

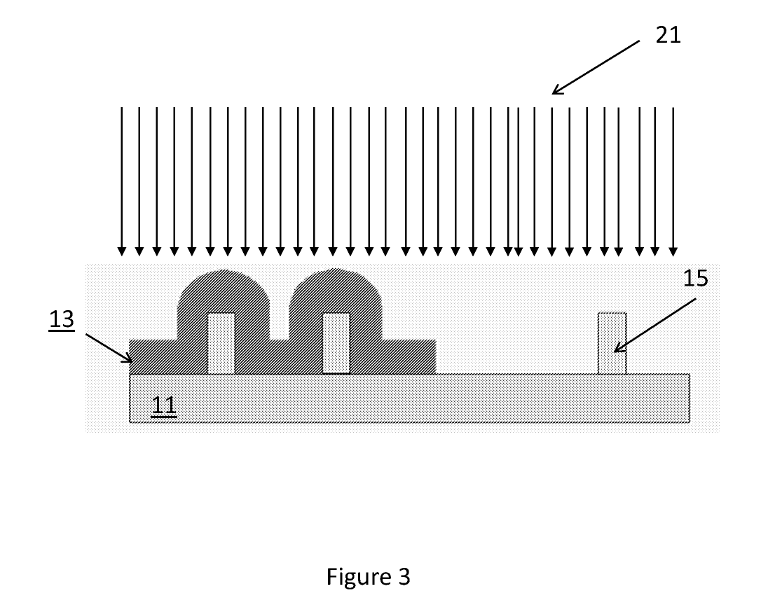

FIG. 3 depicts in another cross section the structure of FIG. 2 following additional process steps. In FIG. 3, an etch has been performed to remove the photoresist 17 and simultaneously removes the portion of the layer 13 that overlies the unmasked portion of the semiconductor region 11. An ion implantation step is illustrated by the downward arrows 21 in FIG. 3. As is known to those of skill in the art, the use of dopant atoms in an implant step may determine or adjust the conductivity type of the semiconductor region 11. Dopants used include boron, arsenic, phosphorus and gallium, for example. Ion implantation can be used to form well regions, source and drain regions, and lightly doped drain regions, and other doped portions of semiconductor devices, all are applications for the embodiments. Other implantations may be performed using the embodiments, as well.

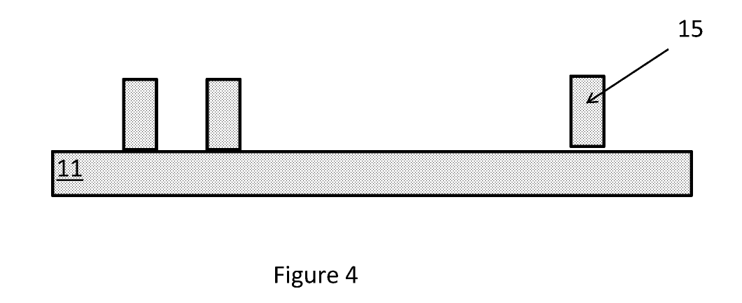

FIG. 4 depicts in a cross sectional view the structure of FIG. 3 following an additional processing step. In FIG. 4, the semiconductor region 11 has been etched to remove the strippable hard mask layer 13. Because the strippable hard mask layer does not form crusty or hard regions in the implantation process, it is easily removed. Using dry etch processes such as plasma ash with O₂, N₂ and H₂ atoms can remove it. Wet etch strippers can remove it as well. Since the strippable hard mask layer 13 is easily removed, no overlong etch cycles are needed that might damage the structures in semiconductor region 11 or layers beneath semiconductor region 11, such as silicon, oxides, and high K and low K dielectric materials. The use of fluorine based strippers is not necessary, which also prevents damage to the underlying structures.

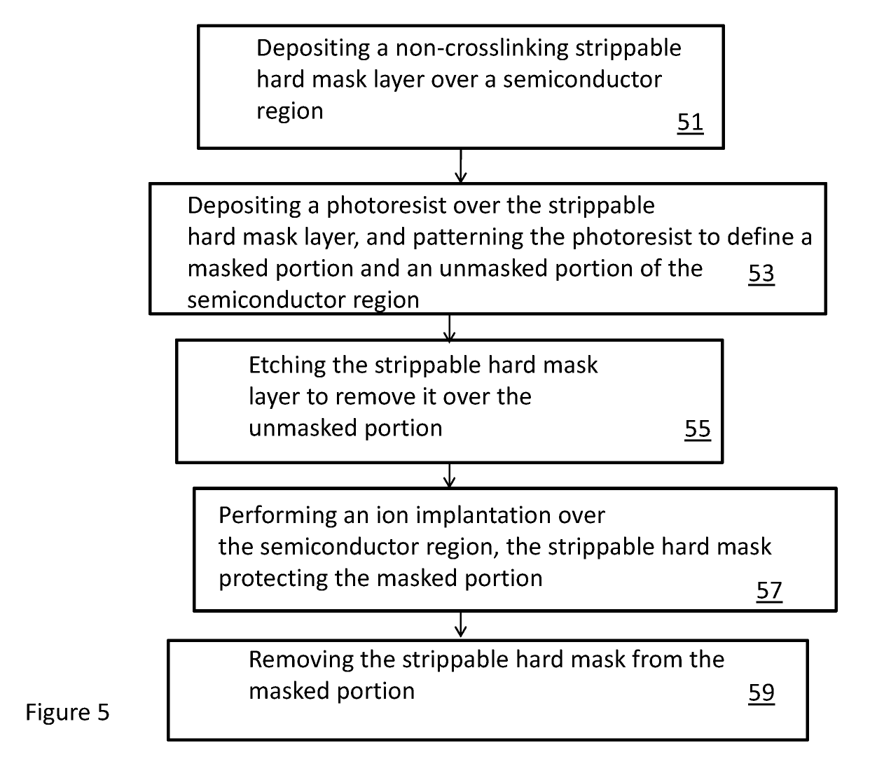

FIG. 5 illustrates, in a flow chart diagram, a method embodiment. In 51, the process begins by depositing the strippable hard mask layer over a semiconductor region. This may be done, for example and without limiting the embodiments, by sputtering or chemical vapor deposition (CVD) or plasma enhanced chemical vapor deposition (PECVD). In an embodiment an amorphous carbon containing layer of a thickness between 400 to 3000 Angstroms may be used. In other embodiments, a room temperature oxide such SiO2 may be used; other materials may be used that are non-crosslinking under ion implantation, act as a mask during ion implantation, and which are easily removed or stripped without damage to the underlying structures of the semiconductor device.

The flow diagram then transitions to a photoresist deposit and patterning step 53. In step 53, a photoresist material is deposited over the strippable hard mask layer and patterned using photolithography to define a masked, and an unmasked, portion of the semiconductor region. The photoresist may be deposited by sputtering or spin on methods, for example, and may have a thickness less than 3000 Angstroms thick. This PR layer is exposed to radiation as is appropriate for the particular photoresist material. Either negative resist or positive resist may be used with the correct photomask. The photoresist is developed with an appropriate developer, which removes the portions that overlie the areas in the semiconductor region which are to be exposed and implanted with dopant ions.

The flow diagram proceeds to step 55. In this step an etch is performed, such as a dry etch including a plasma ash, or a wet etch, to remove the remaining portion of the photoresist layer. At the same time, the strippable hard mask layer overlying the portions of the semiconductor region that are to be implanted is removed, exposing the semiconductor region. However by controlling the thickness of the PR and the etch process, the portions of the strippable hard mask overlying the masked regions is maintained for use as an implantation mask.

In step 57 of the flow diagram, the ion implantation is performed. The implantation can be of dopant concentrations between 1×10¹⁴/cm² and 5×10¹⁶/cm², which require a high dose of implantation energy. Because the strippable hard mask layer of the embodiments does not cross link during ion implantation, it remains easy to remove and free of cross-linking.

In step 59 the process ends by removing the strippable hard mask. Dry and wet etch processes including plasma ashing with O₂, N₂ and H₂ for example may be used. The strippable hard mask is removed without damage to the underlying structures of the semiconductor region.

In a method embodiment, a layer of non-crosslinking mask material is formed over a semiconductor region. A layer of patterned photoresist is formed over the non-cros slinking mask material. The non-crosslinking mask layer not covered by the patterned photoresist layer is removed to form exposed regions and masked regions that remain covered by the non-crosslinking mask layer. The patterned photoresist layer is removed. Ion implantation is performed implanting dopant ions into the exposed regions. The dopant ions being blocked from the masked regions by the non-crosslinking mask layer. The photoresist and the non-crosslinking mask layers are then removed from the masked regions. In an alternative embodiment, the layer of non-crosslinking material comprises carbon. In a further alternative embodiment of the above method, the layer of non-cros slinking material comprises an oxide. In another embodiment of the above method, the semiconductor region is a surface of a semiconductor substrate. In still another embodiment, depositing the layer of non-crosslinking material includes depositing a layer of between 400 and 3000 Angstroms thickness. In yet another embodiment of the above method, depositing the photoresist layer includes depositing a layer having a thickness of less than 3000 Angstroms. In a further embodiment, depositing the layer of non-cros slinking material and the photoresist layer includes depositing two layers with a combined thickness more than 400 and less than 6000 Angstroms. The above method may be performed where removing the photoresist and the non-crosslinking material from the exposed regions includes performing a photoresist development process followed by an etch process. In another embodiment, the etch process is a plasma ash process. The method may also include removing the removing the photoresist layer and the non-crosslinking layer from the masked regions by simultaneously removing the layers by a dry etching process. The dry etching process may be a plasma ash process using a species including any of O₂, N₂ and H₂.

In another embodiment, a method includes forming a strippable hard mask layer over a semiconductor region comprising a semiconductor material and gate electrode materials arranged in stripes over the semiconductor region. A patterned photoresist material is formed over the strippable hard mask layer to define masked regions of the semiconductor region and unmasked regions spaced from the masked regions, the masked regions having photoresist material over the strippable hard mask layer. The strippable hard mask layer is removed from the unmasked regions to form an exposed semiconductor region, the masked regions remaining covered by the strippable hard mask layer. The photoresist material is removed from the masked regions. Ion implantation is performed to implant dopant ions into the exposed semiconductor region; the strippable hard mask layer and any remaining photoresist are then removed from the masked regions. In another embodiment, the method includes forming the strippable hard mask layer by forming a carbon containing layer. In another embodiment, the method includes forming a strippable hard mask layer of a layer of non-crosslinking material. In still another embodiment, forming a strippable hard mask layer comprises forming an oxide. The method may include removing the strippable hard mask layer and any remaining photoresist simultaneously.

In yet another embodiment method, a semiconductor substrate is provided with gate electrodes over the semiconductor substrate. Lightly doped drain regions are formed on either side of at least one of the gate electrodes, by forming a strippable hard mask layer over the semiconductor substrate and the gate electrode. A photoresist material is deposited over the strippable hard mask layer. The photoresist material is patterned in a photolithographic process to define masked regions of the semiconductor substrate and unmasked regions of the semiconductor substrate spaced from the masked regions. The strippable hard mask layer is removed from the unmasked regions of the semiconductor substrate to from an exposed semiconductor region on either side of the at least one of the gate electrodes, the masked regions remaining covered by the strippable hard mask layer. An ion implantation to implant dopant ions into the exposed semiconductor region to form lightly doped drain regions aligned with the at least one gate electrode; and the strippable hard mask layer and any remaining photoresist is removed from the masked regions of the semiconductor substrate. In the method forming the strippable hard mask layer may include depositing a layer of material one selected from the group consisting essentially of a carbon containing layer and an oxide. In an alternative embodiment, forming the strippable hard mask layer includes forming an amorphous carbon layer in a plasma enhanced chemical vapor deposition process. In another embodiment of the method, the lightly doped drain regions are implanted with ions one selected from the group consisting essentially of boron, argon, phosphorous and gallium.

Moreover, the scope of the present application is not intended to be limited to the particular embodiments of the structures, methods and steps described in the specification. As one of ordinary skill in the art will readily appreciate from the disclosure of the present invention, processes, or steps, presently existing or later to be developed, that perform substantially the same function or achieve substantially the same result as the corresponding embodiments described herein may be utilized according to the present invention. Accordingly, the appended claims are intended to include within their scope such processes or steps.

What is claimed is:

1. A method, comprising:
forming a layer of non-cros slinking mask material over a semiconductor region;
forming a layer of patterned photoresist over the non-cros slinking mask material;
removing the non-crosslinking mask layer not covered by the patterned photoresist layer to form exposed regions and forming masked regions that remain covered by the non-crosslinking mask layer;
removing the patterned photoresist; and
implanting dopant ions into the exposed regions, the dopant ions being blocked from the masked regions by the non-crosslinking mask layer.

2. The method of claim 1, wherein forming the layer of non-crosslinking mask material comprises depositing a layer comprising carbon.

3. The method of claim 1, wherein forming the layer of non-crosslinking mask material comprises depositing an oxide.

4. The method of claim 1, wherein the semiconductor region is a surface of a semiconductor substrate.

5. The method of claim 1, wherein forming the layer of non-crosslinking mask material comprises depositing a layer of between 400 and 3000 Angstroms thickness.

6. The method of claim 1, wherein forming the patterned photoresist comprises depositing a photoresist having a thickness of less than 3000 Angstroms.

7. The method of claim 1, wherein forming the layer of non-crosslinking mask material and the photoresist comprises depositing two layers with a combined thickness more than 400 and less than 6000 Angstroms.

8. The method of claim 1, further comprising removing the non-crosslinking mask material from the masked regions.

9. The method of claim 8, wherein removing the non-crosslinking mask material comprises performing a plasma ash process.

10. The method of claim 8, wherein removing the non-crosslinking mask material from the masked regions comprises removing the layer by a dry etching process.

11. The method of claim 10, wherein the dry etching process is a plasma ash process using a species one selected from the group consisting essentially of O₂, N₂ and H₂.

12. A method comprising:
forming a strippable hard mask layer over a semiconductor region comprising a semiconductor material and gate electrode materials arranged in stripes over the semiconductor region;
forming patterned photoresist material over the strippable hard mask layer to define masked regions of the semiconductor region and unmasked regions spaced from the masked regions, the masked regions having photoresist material over the strippable hard mask layer;
removing the photoresist and the strippable hard mask layer from the unmasked regions to form an exposed semiconductor region, the masked regions remaining covered by the strippable hard mask layer;
performing ion implantation to implant dopant ions into the exposed semiconductor region; and
removing the strippable hard mask layer and any remaining photoresist from the masked regions.

13. The method of claim 12, wherein forming a strippable hard mask layer comprises forming a carbon containing layer.

14. The method of claim 12, wherein forming a strippable hard mask layer comprises forming a layer of non-cros slinking material.

15. The method of claim 12, wherein forming a strippable hard mask layer comprises forming an oxide.

16. The method of claim 12, where removing the strippable hard mask layer and any remaining photoresist are performed simultaneously.

17. A method, comprising:
providing a semiconductor substrate;
forming gate electrodes over the semiconductor substrate; and
forming lightly doped drain regions on either side of at least one of the gate electrodes, comprising:
forming a strippable hard mask layer over the semiconductor substrate and the at least one gate electrode;
forming patterned photoresist material over the strippable hard mask layer, defining masked regions covered by photoresist material and unmasked regions not covered by photoresist and spaced from the mask regions;
removing the strippable hard mask layer from the unmasked regions of the semiconductor substrate to form an exposed semiconductor region on either side of the at least one of the gate electrode, the masked regions remaining covered by the strippable hard mask layer; and
performing ion implantation to implant dopant ions into the exposed semiconductor region to form lightly doped drain regions aligned with the at least one gate electrode.

18. The method of claim 17 wherein forming a strippable hard mask layer comprises:
depositing a layer of material one selected from the group consisting essentially of a carbon containing layer and an oxide.

19. The method of claim 17, wherein forming a strippable hard mask layer comprises forming an amorphous carbon layer in a plasma enhanced chemical vapor deposition process.

20. The method of claim 17, wherein performing ion implantation to form the lightly doped drain regions comprises performing implantation with ions one selected from the group consisting essentially of boron, argon, phosphorous and gallium.
